(19) United States
(12) Patent Application Publication
(10) Pub. No.: US 2020/0396983 A1
(43) Pub. Date: Dec. 24, 2020

(54) PATTERNS FOR DETERRING BIRD COLLISIONS, ARTICLES INCLUDING SUCH PATTERNS, AND ASSOCIATED METHODS

(71) Applicant: GUARDIAN GLASS, LLC, Auburn Hills, MI (US)

(72) Inventor: ALEXANDER SOBOLEV, AUBURN HILLS, MI (US)

(73) Assignee: GUARDIAN GLASS, LLC, Auburn Hills, MI (US)

(21) Appl. No.: 16/906,491

(22) Filed: Jun. 19, 2020

Related U.S. Application Data
(60) Provisional application No. 62/864,391, filed on Jun. 20, 2019.

(51) Int. Cl. A01M 29/08; C03C 17/00; C23C 14/34; E06B 3/67

(52) U.S. Cl. CPC A01M 29/08; C03C 17/001; C03C 2217/74; E06B 3/6715; C23C 14/34

(57) ABSTRACT

Certain example embodiments relate to making use of the difference in visually perceivable spectra as between humans and birds to create at least pseudo-random and generally non-repeating patterns that help deter birds from colliding with building facades and other transparent barriers, techniques for creating such patterns, articles including such patterns, and methods of making such articles. The patterns include design elements or areas of a UV-reflective material that is visible to birds and may or may not be easily perceivable to humans. The patterns may be created in accordance with a plurality of design rules embodied in a computer-implemented algorithm. Design rules relate to position, rotation, and/or size randomness of the design elements included in the pattern. Execution of the algorithm defines the pattern. Once the pattern is defined, the transparent substrate can have the pattern applied thereto via any suitable manufacturing technique.

### CROSS-REFERENCE TO RELATED APPLICATION

This application claims the benefit of U.S. Provisional Application Ser. No. 62/864,391 filed on Jun. 20, 2019, the entire contents of which are hereby incorporated herein by reference.

### TECHNICAL FIELD

Certain example embodiments of this invention relate to patterns that help deter birds from colliding with building facades and other transparent barriers, techniques for creating such patterns, articles including such patterns, and methods of making such articles. More particularly, certain example embodiments of this invention relate to making use of the difference in visually perceivable spectra as between humans and birds to create at least pseudo-random and generally non-repeating patterns that help deter birds from colliding with building facades and other transparent barriers, techniques for creating such patterns, articles including such patterns, and methods of making such articles.

### BACKGROUND AND SUMMARY

Birds are incredibly agile, fly at high speeds, and are constantly interacting with the environment around them. Birds tend to be very aware of their body size and, thus, how small of an opening they can fit through.

Birds unfortunately sometimes come into contact with glass surfaces on building facades (including home windows, office buildings, etc.) and other transparent barriers. Birds that fly into windows at a high velocity can injure and sometimes even kill themselves as a result of the contact and/or a subsequent fall, or predation after landing with a collision injury. Interestingly, many birds that most often are victims of collisions have a near 360 degree field of view or spatial awareness but oftentimes have no or limited binocular vision. This suggests that, in flight, birds tend to look at their surrounding environment (e.g., for food or predators) rather than looking ahead at where they are going.

The sources of this problem can in some instances be linked to light reflection and light transmission complications, as well as the tendency to see in the manner described above. For instance, birds can mistake reflection on the surface of glass for extensions of the natural environment. Even low reflection glass can act like a mirror when it is bright outside and dark inside. In fact, when coupled with certain façade designs, reflections can create areas that are so visually confusing that the birds do not know how to escape (like a funhouse mirror maze).

In the context of reflection, for example, in applications where there is a direct line of sight from one window to another (such as might be the case with walkways, corner offices, bus stops, etc.), birds do not necessarily perceive the glass as a barrier and may attempt to fly through. In fact, in atriums with indoor plants, the space can seem to be an inviting habitat into which some birds will attempt to fly. And similar to the confusion caused by reflection that creates a funhouse effect, birds can often become trapped in glass enclosures that are similar to tunnels or the like, as there is no obvious difference to birds between open exits and glass.

Birds basically perceive a spectrum similar to that perceivable by humans in that, as a general rule of thumb, if something can be perceived by a human, it also can be perceived by a bird. However, birds also have some vision that extends into the ultraviolet range. The UV tends to be a weaker signal perceivable by some birds, but it nonetheless means that there are frequency ranges that are perceivable by some birds that are not also perceivable by humans.

Some current products that attempt to deter birds from colliding with building facades and other transparent barriers attempt to make use of the difference in perception between birds and humans. For instance, it is possible, at least in theory, to provide to a glass or other transparent substrate a thin film or other coating that is perceivable in the UV range and thus to birds that is not also perceivable by humans. In this regard, some current products provide patterns across the surface of the substrate. Such patterns typically are generally linear arrangements of lines or dots that are sized and spaced in accordance of best practices determined by avian researchers.

Unfortunately, however, such standard pattern designs oftentimes need to be carefully designed and aligned as they are being prepared for inclusion into a transparent article (such as, for example, an insulated glass or other window unit for a building, transparent barrier at a lookout, bus stop, and/or the like). This can impose design and manufacturing hurdles. For instance, some designs are largely ineffective for some orientations in that they can deter bird collisions if installed in a vertical but not horizontal manner. Generally, current grid-like designs make manufacturing challenging, as up to 50% of the yield can be lost if installed in a vertical orientation. Misalignments, misregistrations, and/or the like, also can create small gaps or areas that birds can fly into. It also would be desirable to increase the overall effectiveness of the patterns.

Certain example embodiments address the above-described and/or other issues. For instance, certain example embodiments help deter birds from colliding with building facades and other transparent barriers, e.g., by making use of the difference in visually perceivable spectra as between humans and birds. One aspect of certain example embodiments relates to providing patterns of design elements to transparent substrates that are effective in this regard. Another aspect of certain example embodiments relates to simplistic manufacturing and installation procedures, e.g., enabling patterns to be applied to substrates so that those substrates can be used in a variety of different orientations in a variety of different products without sacrificing effectiveness. Certain example embodiments advantageously enable cutting and sizing without regard for the pattern orientation. In other words, certain example embodiments advantageously are highly functional regardless of how the substrates are cut, sized, installed, etc.

The patterns of certain example embodiments may be produced according to a computer-implemented algorithm that creates an at least pseudo-random and generally non-repeating pattern in this regard. For instance, design rules may relate to position, rotation, and/or size randomness of the design elements included in the pattern. These features may work together to help create an average design element density that provides openings or areas where design elements are not larger than a given size (e.g., approximately 2″ by 2″ or 2″ by 4″ in size).

In certain example embodiments, a coated article is provided. A substrate supports a UV blocking coating on an exterior major surface thereof. The UV blocking coating is discontinuous and patterned to form a plurality of design elements, the design elements being positioned across the major surface of the substrate, and the design elements being sized, shaped, and arranged such that at least some design elements are oriented at angles that are neither normal nor substantially normal nor parallel nor substantially parallel to at least some of the other design elements, and such that openings between design elements in the UV blocking coating on average are no greater than a predetermined surface area.

In certain example embodiments, a method of making a coated article comprises: having a substrate; and forming a UV blocking coating on an exterior major surface thereof. The UV blocking coating is discontinuous and patterned to form a plurality of design elements, the design elements being positioned across the major surface of the substrate, and the design elements being sized, shaped, and arranged such that at least some design elements are oriented at angles that are neither normal nor substantially normal nor parallel nor substantially parallel to at least some of the other design elements, and such that openings between design elements in the UV blocking coating on average are no greater than a predetermined surface area.

A laminated product and/or insulating glass (IG) unit incorporating such a coated article, and methods of making the same, also are contemplated herein and also are provided by certain example embodiments.

Also contemplated herein, and also provided by certain example embodiments, is a method of making a pattern template for use in creating the pattern, the method comprising executing computer-programmed instructions to define the pattern and/or pattern template. Certain example embodiments, relate to a non-transitory computer readable storage medium storing instructions that, when executed, execute such a method. Similarly, certain example embodiments relate to a computing system comprising at least one processor and a memory, the memory storing such instructions that are executable to perform such a method.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 shows typical dimensions of a hummingbird;

FIG. 2 is an image showing articles with different size and different density design elements provided thereto;

FIG. 3 is an example mask that may be used to create a pattern of design elements in accordance with certain example embodiments;

FIG. 4 is an example pattern produced in accordance with certain example embodiments;

FIG. 5 is another example pattern produced in accordance with certain example embodiments;

FIG. 6 is a variant of FIG. 5 in that it includes generally circular design elements with each being composited from multiple other circular design elements, in accordance with certain example embodiments;

FIG. 7 is an example pattern that helps demonstrate further design variables that may be controlled for in accordance with certain example embodiments;

FIG. 8 is a cross-sectional view of a coated article incorporating a pattern in accordance with certain example embodiments;

FIG. 9 is a cross-sectional view of an insulated glass (IG) unit incorporating a pattern in accordance with certain example embodiments;

FIG. 10 is a cross-sectional view of another insulated glass (IG) unit incorporating a pattern in accordance with certain example embodiments;

FIG. 11 includes a plurality of different patterns that may be used in connection with certain example embodiments; and

FIGS. 12-16 show how a pattern can be generated and how the basic dimensions, shapes, arrangements, overlaps, orientations, and/or other features of the pattern's design elements can be manipulated in accordance with certain example embodiments.

### DETAILED DESCRIPTION

Certain example embodiments relate to making use of the difference in visually perceivable spectra as between humans and birds to create at least pseudo-random and generally non-repeating patterns that help deter birds from colliding with building facades and other transparent barriers, techniques for creating such patterns, articles including such patterns, and methods of making such articles. The patterns include design elements or areas of a UV-reflective material that is visible to birds and may or may not be easily perceivable to humans. For example, it is noted that the UV-reflective coating may reflect UV and also reflect at least some light that is visible to humans. In such situations, the color of the visible portion may be controlled for aesthetic and/or other purposes, while the UV reflective coating as a whole has an increased effectiveness in terms of deterring bird collisions. The patterns may be created in accordance with a plurality of design rules embodied in a computer-implemented algorithm. Execution of the algorithm defines the pattern. Once the pattern is defined, the transparent substrate can have the pattern applied thereto via any suitable manufacturing technique, e.g., as described in greater detail below.

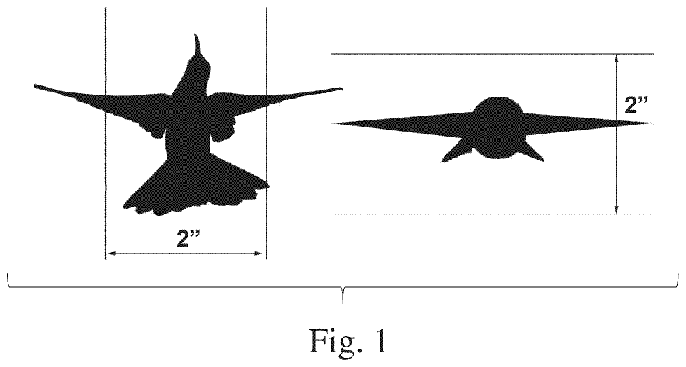

Regarding the collision and other issues discussed above, it is believed that hummingbirds are one of the smallest highly-affected species of birds. FIG. 1 shows typical dimensions of a hummingbird. As can be seen from FIG. 1, hummingbirds may sometimes try to fit through openings, real (as in gaps between physical materials) or perceived (as in the case of glass that does or does not have a pattern applied thereto), that are larger than about 2″ by 2″. However, it has been observed that hummingbirds generally will avoid flying through real gaps that are 2″ by 2″ or 2″ by 4″. Certain example embodiments thus may attempt, at least at a high level and subject to the relaxations on constraints discussed below (e.g., where effective bird collision deterrence can be achieved even though there is larger element spacing), to create patterns that include a plurality of design elements, with gaps between the design elements generally adhering to this “2×4 rule” or “2×2 rule.” That is, the patterns of certain example embodiments may include gaps between design elements, or negative space, that is/are no more than 2″ by 2″ in size or no more than 2″ by 4″ in size. Additionally, or in the alternative, certain example embodiments may produce patterns where at least some of the design elements are angled and/or erratic, such that they are not all generally horizontal or all generally vertical, relative to the installation. Doing so may help ensure that the articles can be installed in any orientation (including, for example, a generally horizontal configuration or a generally vertical configuration). Moreover, angled and erratic design element patterns may in some instances allow for larger spacing of elements. Most research focuses on length and width type spacing in a grid-type approach, but it is believed that angled designs may be effective in deterring bird collisions while permitting a broader spacing.

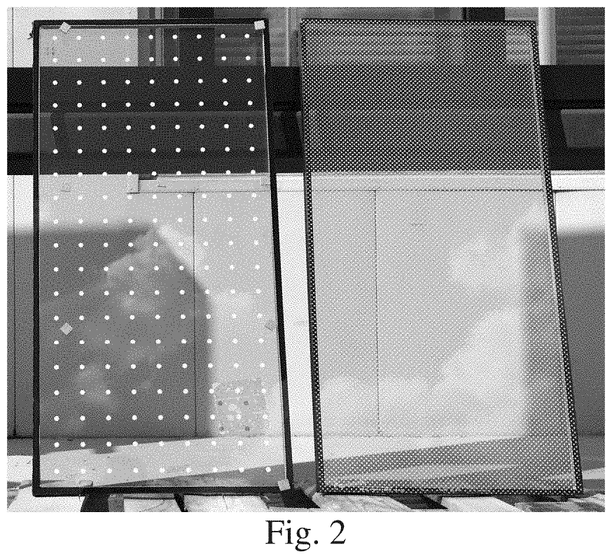

The patterns of certain example embodiments may include design elements located to provide for a suitable contrast perceivable to a bird. In this regard, a small dense pattern typically will be less visible from a distance or at speed, compared to a larger element larger density pattern even if the same percentage of surface area is covered. It also is noted that the same color might be visible on one background and not another. With respect to the former, FIG. 2 is an image showing articles with different size and different density design elements provided thereto. The article on the left-hand side of FIG. 2 has larger elements with a smaller density compared to the article on the right-hand side of FIG. 2. The elements on the article on the left are much more easily perceived. Thus, certain example embodiments may seek to create a suitable visual contrast using uniformly colored (and sometimes non-uniformly colored) design elements that are visible against a variety of different backgrounds. Additionally, or in the alternative, certain example embodiments may seek to create a pattern with a larger density and/or larger elements.

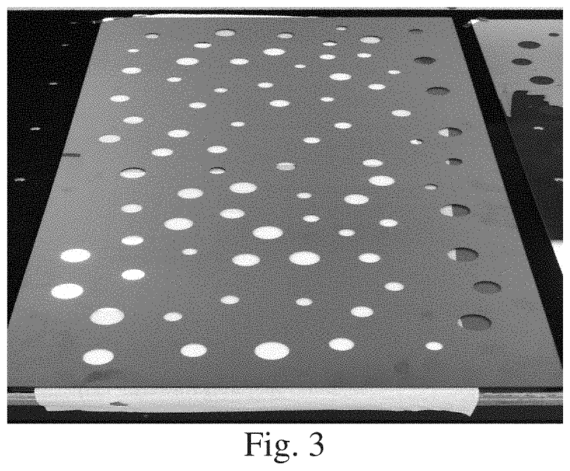

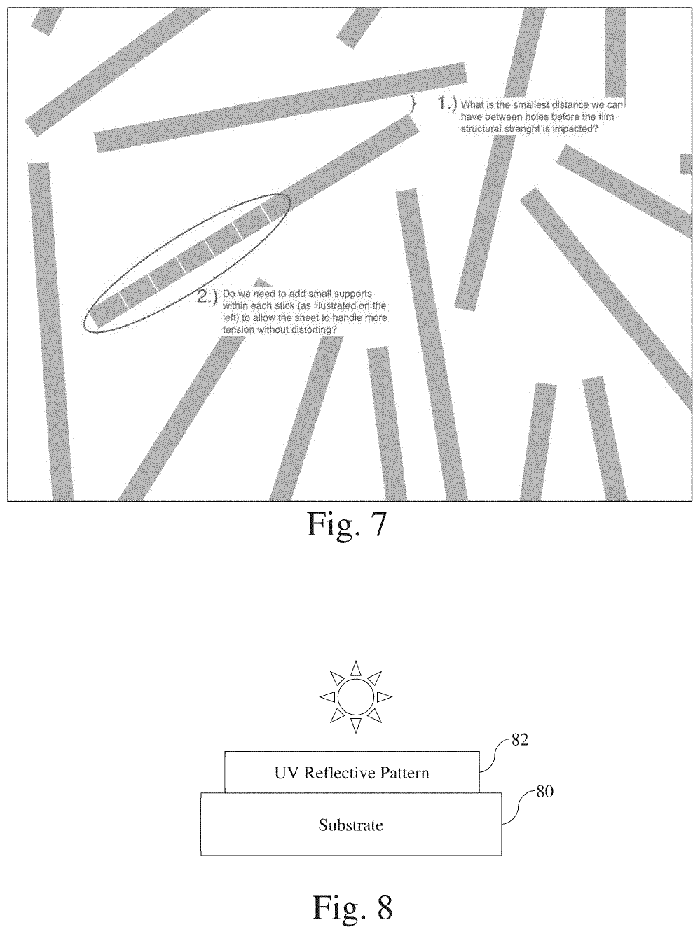

The patterns of certain example embodiments may be produced using any suitable manufacturing technique. In certain example embodiments, a pattern mask or template may be created and used to pattern a film or the like. Positive and negative type masks may be used in different example embodiments. For instance, ink masking, plate masking, die-cut film masking, photolithography, and/or the like, may be used. In certain example embodiments, a mask formed in accordance with a designed pattern may be applied over an article onto which the pattern is to be formed. Material in the form of ink, a thin film, and/or the like, may be added onto the article so as to create the design elements. That is, material in the form of an ink, thin film, or the like, may be provided through holes defined in the mask that correspond with the design elements placed in the pattern. FIG. 3 is an example mask that may be used to create a pattern of design elements in accordance with certain example embodiments. For instance, the mask may be applied over a substrate to be coated, and the covered substrate may be inserted into a sputtering chamber so that a UV reflecting film is applied onto the substrate through the holes in the mask. Alternatively, the mask may be applied over a substrate to be coated, and the covered substrate may have ink injected into or ejected proximate to the holes, so as to form the design elements. In certain example embodiments, a UV coating may be blanket coated onto a substrate and removed via a laser, etching (e.g., using an acid or other wet chemical), or the like. The laser may or may not use a mask. Similarly, a high-resolution inkjet or other printer may not need a mask. The pattern may be formed onto an unrollable film in some instances, and this film may be provided to (e.g., rolled out over or otherwise adhered to) the major surface of the article. Because the above-listed and other manufacturing techniques have constraints (e.g., in terms of resolution of printing, fineness of edges, thicknesses of coatings, durability, etc.), modifications to a pattern may be made to account for the same, even though the same pattern or template may be used as a base. For instance, ink has a tendency to spread (and can be encouraged to spread using surfactants or the like) and, thus, a mask for use with inks may include holes that closely match the desired design elements. On the other hand, sputtering may not include enough material proximate to the interior walls defining the holes, so such holes may be designed to be somewhat larger or differently shaped compared to the “ideal” pattern. Further modifications that might be desirable depending on the particular manufacturing technique used are discussed below, e.g., in connection with FIG. 7.

It will be appreciated that the three previous paragraphs help define the general solution space. In addition to some or all of these solution space considerations, some or all of the four following “top-level rules” may be imposed on the design. Configuration modifications to each top-level rule also are discussed.

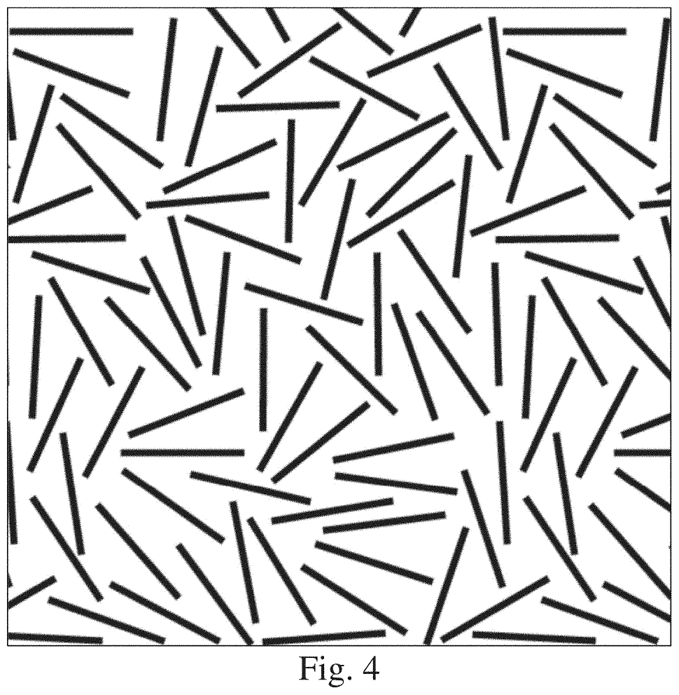

Example Design Rule 1: All design elements in the pattern are to be the same. For example, the design elements may be a common geometry. The common geometry may be generally rectangular, generally circular, generally elliptical or the like. The individual elements all may have the same dimensions. For example, the length and width may be the same for each generally rectangular element, the radius may be the same for each generally circular element, the major and minor radii may be the same for each generally elliptical element, etc. FIG. 4 is an example pattern produced in accordance with certain example embodiments. FIG. 4 include generally rectangular elements that are all the same size, except that those elements at the edges have been modified as discussed in greater detail below. In other words, all or substantially all of the design elements have identical or substantially identical dimensions (e.g., such that they vary by no more than a manufacturing tolerance, no more than a predetermined percentage such as 5-10%, etc.), and potentially with exceptions being provided for at the edges.

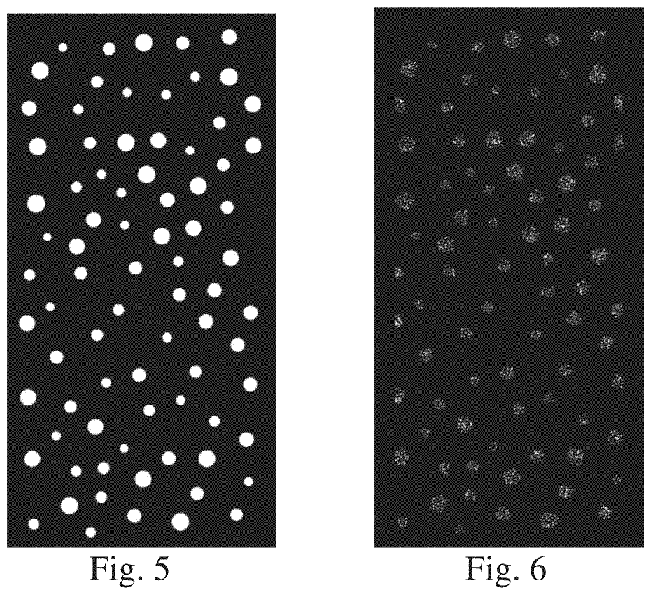

FIG. 5 is another example pattern produced in accordance with certain example embodiments. The FIG. 5 example includes only generally circular elements. However, the strictness of the rule has been relaxed to permit differently sized design elements. That is, in the FIG. 5 example, circles of different radii are provided. In certain example embodiments, each design element may appear to be consistent and unitary at a certain level of examination. However, certain example embodiments may actually composite the same or similar shapes to create these views. FIG. 6 is a variant of FIG. 5, in that FIG. 6 includes generally circular design elements with each being composited from multiple other circular design elements. This also may be thought of as using the original pattern as a bounding box or perimeter to enclose another smaller pattern.

A user interface displayed on an electronic device such as a computer or the like may enable a user to impact how the pattern is formed. For instance, a first user interface element set may enable selection of the basic design element shape (e.g., rectangle, circle, ellipse, etc.). A second user interface element set may enable attributes of the selected shape to be modified. For instance, slider bars or the like may be used to control the length and width of rectangular elements, the radius of circular elements, etc. In certain example embodiments, randomness may be injected with respect to the size of the elements. For instance, size ranges may be specified using the second user interface elements, prompting the algorithm to provide individual elements within a specified size distribution. Although regular geometric patterns are described, modifications can be made thereto, e.g., to enable rounding of corners, gradients, replacement with other designs such as logos or the like, etc. A third user interface element set such as a series of checkboxes may enable or disable compositing similar to that described in connection with FIGS. 5-6. A fourth user interface element set may enable primary, secondary, tertiary, and/or other shapes to be selected, so that multiple shapes can be selected for a pattern. These elements may be used, for example, to specify common shapes but then influence how the common shapes are sized (e.g., so that rectangular elements can be mixed with circular elements, so that a first set of circular elements has a first common radius while a second set of circular elements has a second common radius, etc.).

Example Design Rule 2: Pattern elements are arrayed in random positions and rotations. Random positioning and rotation is apparent from FIG. 4, for example. In certain example embodiments, a user may be provided with a “preview” of the pattern. The user may then select elements and move and/or rotate a selected element. The user interface in some instances may prevent user manipulation such as movements and/or rotations to prevent the example design rules from being violated. In some other instances, the user interface may simply permit these user manipulations (but may in some instances provide a warning if a rule has been or is in danger of being violated). In still other instances, the user interface may permit these user manipulations but then may reposition and/or reorient other elements so that the design rules are met, e.g., automatically or after user confirmation that that processing should be performed. User manipulated elements in such instances may be “fixed” and the algorithm may simply work around them as if they were restrictions.

Example Design Rule 3: Pattern elements do not overlap. This can be seen in each of the FIG. 4-6 examples. The user interface adjustments described in the previous paragraph may be implemented here, as well. For instance, slider elements may be used to control for spacing between design elements. It will be appreciated that some patterning techniques will not allow for overlapping patterns and, thus, in cases where this rule is relaxed so as to be unenforced, overlap may not be provided. Instead, a singular hole in a mask corresponding to two partially overlapping shapes may be provided.

Example Design Rule 4: The negative space (packing) between pattern elements should satisfy a dimensionality requirement. For example, openings larger than a predetermined length and width or predetermined radius should not be permitted. The 2×4 or 2×2 rule may be employed in certain example embodiments. A user interface element may be provided so as to enable the user to adjust the density and/or change the dimensionality requirement. A slider bar may be used in this regard in certain example embodiments. It will be appreciated that his rule may be enforced within a tolerance in certain example embodiments. For instance, as can be seen in the upper-left corner of FIG. 4, a narrow slit persists, implying (for example) a 2″×10″ opening. This opening nonetheless may be sufficient in certain example embodiments as it nonetheless may be effective in reducing the likelihood of bird collisions.

Softer rules or guidance may be used to tune the algorithm in certain example embodiments. In this regard, in some instances, pattern design elements at or near one or more edges of the pattern might need or benefit from special treatment such as, for example, shortening while maintaining a square end. Doing so may help ensure Example Design Rule 4 is met, even though Example Design Rule 1 might be somewhat strained or compromised in limited areas. Several elements along the right edge of FIG. 4 show this compromise.

Depending on the pattern size, edge elements may be repeated so as to cover a desired surface area of the transparent panel. This also may be necessary or desirable depending on the manufacturing method. For instance, if the design is adapted for use with a drum die cutter, the pattern may be made to seamlessly repeat along one axis.

It will be appreciated that grid-like patterns are avoided in certain example embodiments. For instance, certain example embodiments include at least some design elements that are oriented at angles that are neither normal nor substantially normal nor parallel nor substantially parallel to at least some of the other design elements. In this regard, substantially normal and substantially parallel means normal and parallel, respectively, within a threshold such as, for example, a threshold dictated by manufacturing tolerances or up to a given percentage such as, for example, 5%, 10%, 15%, or the like.

FIG. 7 is an example pattern that helps demonstrate further design variables that may be controlled for in accordance with certain example embodiments. As shown in the first enumerated area of FIG. 7, consideration may be given to the minimum distance between pattern elements. This distance could be difficult to manufacturer and/or could affect structural strength of the film as a whole is impacted. A minimum distance variable thus may be taken into account in connection with example design rules 2-4 in certain example embodiments. As shown in the second enumerated area of FIG. 7, consideration may be given to the type of production such that the pattern may need to be subdivided or otherwise reinforced, e.g., to maintain the structural integrity of the masking material.

In general, the patterns shown in FIGS. 4-7 may have design elements of any suitable dimensions. For instance, dot-like patterns may have a diameter of ⅛″ to 12″, more preferably ¼″ to 8″, still more preferably ¼″ to 4″, and still more preferably ¼″ to 2″. In some instances, dots smaller than ¼″ may be used if they make up a finer pattern that fill another shape such as a circle, rectangle, or the like. In certain example embodiments, such dot patterns preferably have diameters no smaller than ¼″. Rod-like patterns may have major and/or minor dimensions of 1/16″ to 24″, more preferably ⅛″ to 12″. All values and sub-ranges therein are contemplated, and it is noted that square patterns where the length and width is the same and thus there is no major or minor dimension per se, may be used in certain example embodiments. It is noted that the thickness and length variables may be determined independently from each other, e.g., based on the density of the pattern and/or other factors, particularly if the minimum dimension is at least about ¼″.

FIG. 8 is a cross-sectional view of a coated article incorporating a pattern in accordance with certain example embodiments. A transparent substrate 80 may be a glass, plastic, or other substrate. It supports a UV reflective coating 82 on the major surface adjacent to the exterior of the structure (i.e., surface 1). The placement of the coating 82 on surface 1 is advantageous in that placement on surface 2 likely would be ineffective given the reflection caused by surface 1 and/or UV attenuation caused by the substrate 80. UV reflective coatings that may be used in this regard are disclosed in U.S. Application Ser. No. 62/764,671 filed Aug. 15, 2018 (which corresponds with WO 2020/035818) and Ser. No. 16/906,394 filed Jun. 19, 2020; U.S. Publication Nos. 2014/0168760 and 2019/0084874; and U.S. Pat. Nos. 8,114,488; 8,389,077; and 9,650,290, the entire contents of each of which are hereby incorporated herein by reference.

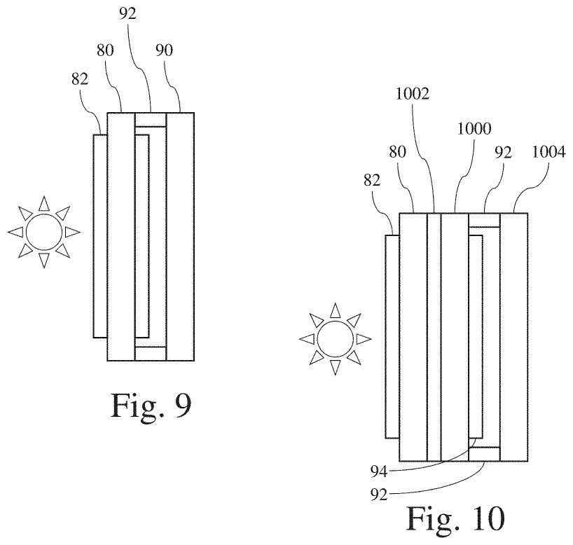

FIG. 9 is a cross-sectional view of an insulated glass (IG) unit incorporating a pattern in accordance with certain example embodiments. The FIG. 9 IG unit also includes first substrate 80 supporting a UV reflective coating 82 on an outer surface thereof. The first substrate 80 is substantially parallel to and spaced apart from a second substrate 90. A spacer system 92 helps maintain the substrates 80, 90 in substantially parallel spaced apart relation to one another. The gap between the substrates 80, 90 may be filed with air, an inert gas (e.g., Ar, Kr, Xe, and/or the like), or some mixture thereof. Functional coatings may be provided on one or more surfaces of the IG unit apart from the first surface. The functional coatings may include antireflection (AR), low-emissivity (low-E), and/or other coatings. In the FIG. 9 example, a low-E coating 94 is provided on an inner surface of the outer or first substrate 80, i.e., on surface 2. A low-E or other thermal related coating may be provided on surface 3 (i.e., the major surface of the second substrate 90 that faces the first substrate 80).

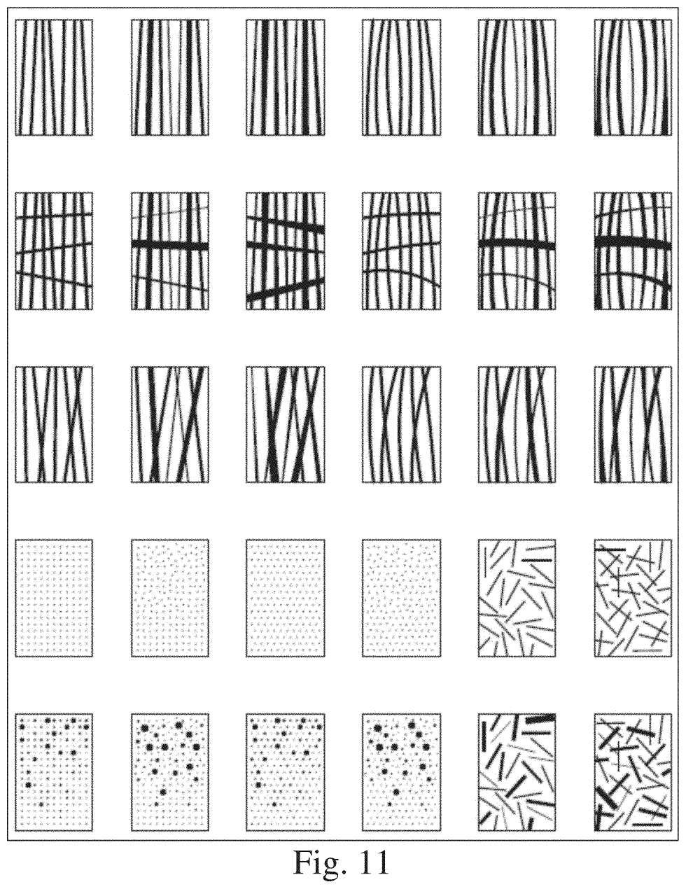

FIG. 10 is a cross-sectional view of another insulated glass (IG) unit incorporating a pattern in accordance with certain example embodiments. FIG. 10 includes an outermost, first substrate 80 that supports a UV reflective coating 82. The outermost substrate 80 is laminated to another, second substrate 1000 via a laminating layer 1002. The laminating layer 1002 may be a polymer-based interlayer or the like. PVB, EVA, PU, or other materials may be used in connection with the laminating layer 1002. The second substrate 1000 is substantially parallel and spaced apart from a third substrate 1004. A spacer system 92 helps maintain the substrates 1000, 1004 in substantially parallel spaced apart relation to one another. As above, the gap between substrates 1000, 1004 may be filed with air, an inert gas (e.g., Ar, Kr, Xe, and/or the like), or some mixture thereof. Also as above, functional coatings may be provided on one or more surfaces of the IG unit apart from the first surface. In the FIG. 10 example, the low-E coating 94 is provided fourth surface of the IG unit. A low-E or other thermal related coating may be provided on surface 5 (i.e., the major surface of the third substrate 1004 that faces the second substrate 1000).

FIG. 11 includes a plurality of different patterns that may be used in connection with certain example embodiments. It will be appreciated that the various patterns provided in FIG. 11 conform to various ones of the design rules discussed above, while relaxing others.

It will be appreciated that the example techniques described herein may be used in connection with a variety of transparent panels and transparent panel types. This includes, for example, glass, plastic, and/or other substrates, used in monolithic, insulated glass (IG), vacuum insulated glass (VIG), laminated, and/or other products. These products may be used in a variety of applications such as, for example, windows in residential and commercial settings, architectural elements, greenhouses, and/or the like.

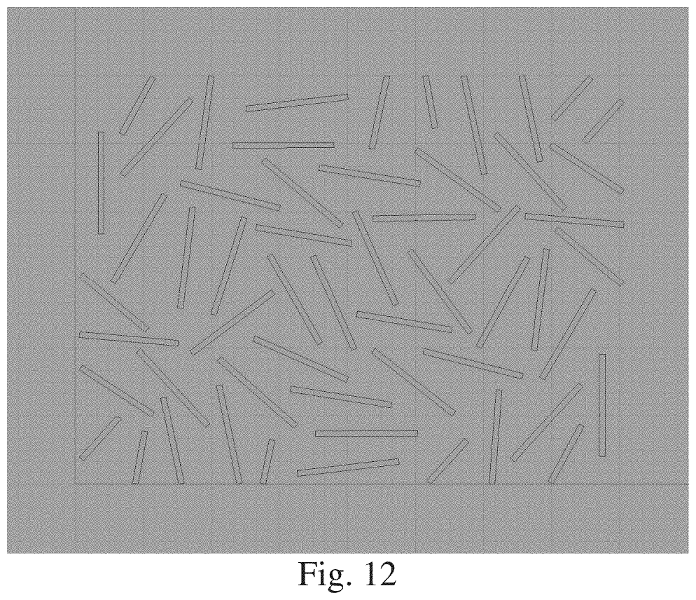

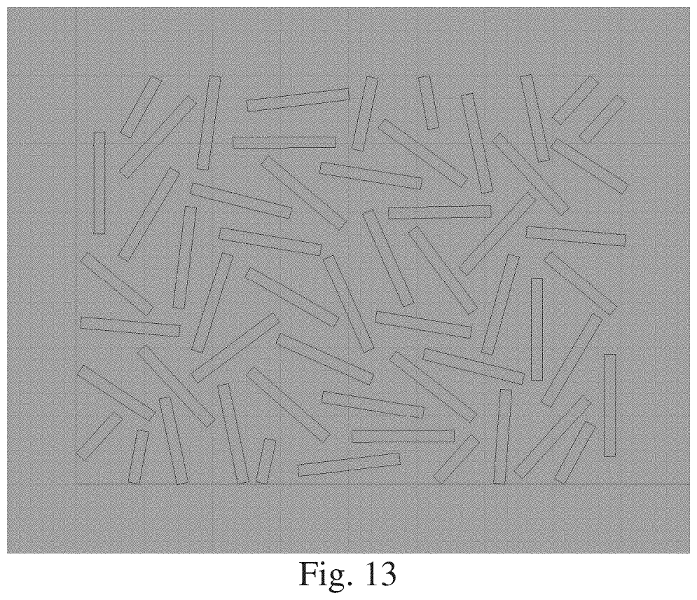

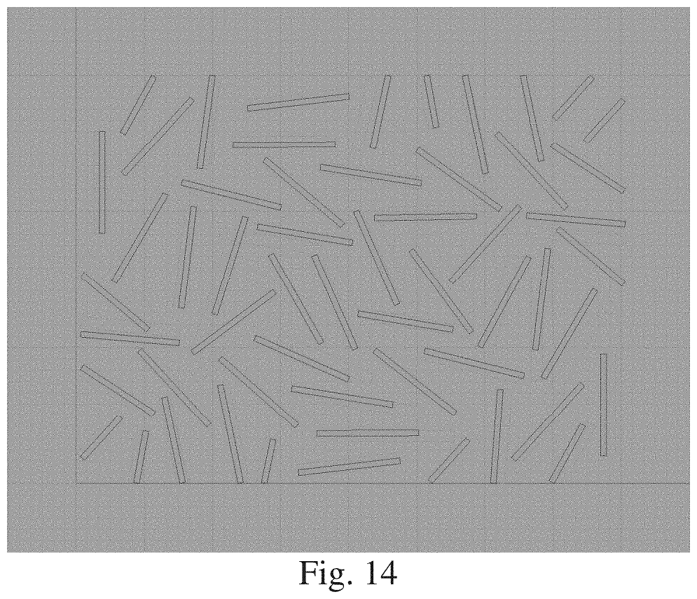

FIGS. 12-16 show how a pattern can be generated and how the basic dimensions, shapes, arrangements, overlaps, orientations, and/or other features of the pattern's design elements can be manipulated in accordance with certain example embodiments. Manipulations of the types show in and described in connection with FIGS. 12-16 (and/or others) may be performed using the software-based tool described herein. In greater detail, FIG. 12 shows a basic rectangular nesting of elements in accordance with certain example embodiments. The FIG. 12 design comports, or essentially comports, with the design rules set forth above. FIG. 13 shows the same basic pattern as FIG. 12, except that the design elements have their widths doubled. The algorithm adjusts the layout in FIG. 13 relative to FIG. 12 to optimize for the new design element width. Thus, the positions and/or orientations of at least some of the design elements are altered automatically by the algorithm to comply or substantially comply with the rules and based on the desired change(s) (e.g., changes to the aspect ratio of the design elements). FIGS. 12-13 in this sense help show that the algorithm of certain example embodiments is adaptive based on dynamic adjustments of the variables (such as, for example, length, width, density, overlap amount, etc.) by the user. FIG. 14 shows the design elements of FIGS. 13-14 on a common “canvas,” further highlighting this functionality by showing the changes involved in going from FIG. 13 to FIG. 14.

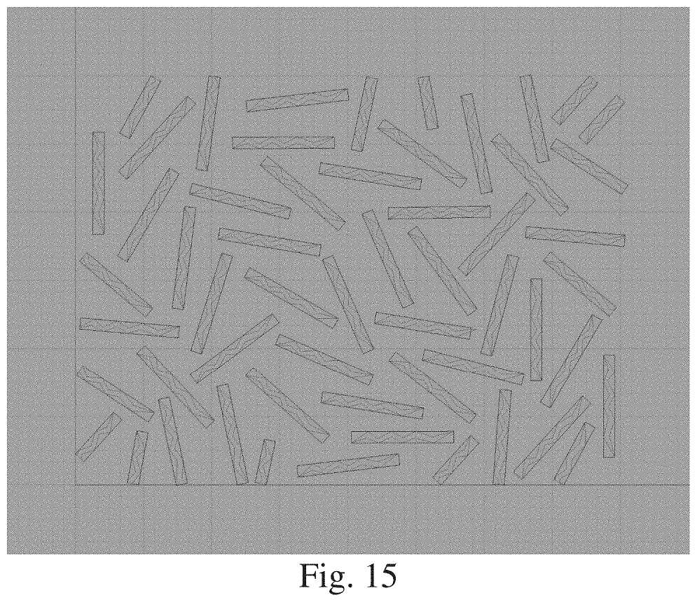

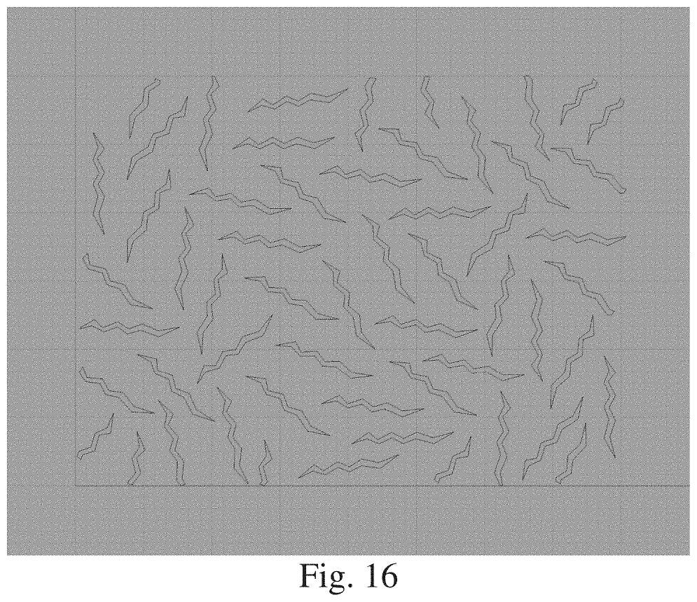

FIGS. 15-16 helps show how certain example embodiments may quickly create customization using a basic rectangular nesting algorithm, in accordance with certain example embodiments. FIG. 15 shows a new design element being incorporated into the nested rectangle pattern of FIG. 12. First, the aspect ratio is changed in accordance with the change from FIG. 12 to FIG. 13. Then, a saw-tooth like design is applied to each of the design elements, using the design elements in essence as “bounding boxes” for the saw-tooth like design locations. The result is shown in FIG. 16. The same or similar principle can be used to understand how micro-circle arrays may be used to create a composite shape or the like.

Although hummingbirds are mentioned, the techniques disclosed herein may be optimized for sizes and/or vision related to songbirds or passerines, or other flying birds or animals.

The terms “heat treatment” and “heat treating” as used herein mean heating the article to a temperature sufficient to achieve thermal tempering and/or heat strengthening of the glass inclusive article. This definition includes, for example, heating a coated article in an oven or furnace at a temperature of at least about 550 degrees C., more preferably at least about 580 degrees C., more preferably at least about 600 degrees C., more preferably at least about 620 degrees C., and most preferably at least about 650 degrees C. for a sufficient period to allow tempering and/or heat strengthening. This may be for at least about two minutes, or up to about 10 minutes, in certain example embodiments. These processes may be adapted to involve different times and/or temperatures.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

In certain example embodiments, a coated article is provided. A substrate supports a UV blocking coating on an exterior major surface thereof. The UV blocking coating is discontinuous and patterned to form a plurality of design elements, the design elements being positioned across the major surface of the substrate, and the design elements being sized, shaped, and arranged such that at least some design elements are oriented at angles that are neither normal nor substantially normal nor parallel nor substantially parallel to at least some of the other design elements, and such that openings between design elements in the UV blocking coating on average are no greater than a predetermined surface area.

In addition to the features of the previous paragraph, in certain example embodiments, the design elements may not overlap one another. Alternatively, in addition to the features of the previous paragraph, in certain example embodiments, at least some of the design elements may overlap one another, e.g., in a manner and/or to an extent specified by a user.

In addition to the features of either of the two previous paragraphs, in certain example embodiments, the design elements may have a common shape.

In addition to the features of the previous paragraph, in certain example embodiments, the common shape may be, for example, substantially rectangular, substantially circular, etc.

In addition to the features of any of the four previous paragraphs, in certain example embodiments, the design elements may have a common shape and at least some of the design elements may have different surface areas compared to at least some of the other design elements.

In addition to the features of any of the five previous paragraphs, in certain example embodiments, the design elements may be substantially rectangular and share a common length or a common width, or may be substantially circular and have varying radii.

In addition to the features of any of the six previous paragraphs, in certain example embodiments, the design elements may have different surface areas that have a predefined average surface area and/or vary by no more than a predefined amount.

In addition to the features of any of the seven previous paragraphs, in certain example embodiments, all or substantially all of the design elements may have identical or substantially identical dimensions.

In addition to the features of the previous paragraph, in certain example embodiments, design elements proximate to one or more peripheral edges of the substrate may not be dimensioned to be identical or substantially identical to other design elements.

In addition to the features of any of the nine previous paragraphs, in certain example embodiments, each design element may be a composite of multiple design elements, e.g., a composite of multiple design elements of the same general shape.

In addition to the features of any of the 10 previous paragraphs, in certain example embodiments, the predetermined surface area may be defined by a length and width.

In addition to the features of the previous paragraph, in certain example embodiments, the predetermined surface area may be approximately 2″ by 2″ or 2″ by 4″.

In addition to the features of any of the 12 previous paragraphs, in certain example embodiments, the predetermined surface area may be defined at least in part based on a specified wingspan and/or height dimension.

In addition to the features of any of the 13 previous paragraphs, in certain example embodiments, design elements may be sized, shaped, and arranged so as to have a density that varies across the major surface of the substrate.

In addition to the features of any of the 14 previous paragraphs, in certain example embodiments, the substrate may be a glass substrate.

In addition to the features of any of the 15 previous paragraphs, in certain example embodiments, the positions, rotations, and/or sizes of the design elements may be determined randomly.

In addition to the features of any of the 16 previous paragraphs, in certain example embodiments, the positions, rotations, and/or sizes of the design elements may be determined randomly within one or more bounded range(s), e.g., with the bounded range(s) potentially being defined in connection with respective minimum and/or maximum values.

In certain example embodiments, there is provided a laminated product, comprising: a second substrate; and a laminating material laminating together the second substrate and the coated article of any of the 17 previous paragraphs such that the UV blocking coating is oriented away from the second substrate. In certain example embodiments, there is provided an insulating glass (IG) unit, comprising: the coated article of any of the 17 previous paragraphs; a second substrate; and a spacer system helping to maintain the coated article and the second substrate in substantially parallel spaced apart relation to one another, such that a gap is formed between the coated article and the second substrate and such that the UV blocking coating is oriented away from the second substrate.

In addition to the features of the previous paragraph, in certain example embodiments, the gap may be at least partially filled with an inert gas.

In addition to the features of either of the two previous paragraphs, in certain example embodiments, a low-emissivity coating may be provided on a surface of the coated article facing the gap and/or a surface of the second substrate facing the gap.

In addition to the features of any of the three previous paragraphs, in certain example embodiments, a third substrate may be provided, e.g., with the third substrate being laminated to the coated article via a laminating material, and with the third substrate being interposed between the coated article and the second substrate.

In addition to the features of the previous paragraph, in certain example embodiments, a low-E coating may be provided on a surface of the second substrate facing the gap.

In certain example embodiments, a method of making a coated article is provided. The method includes having a substrate; and forming a UV blocking coating on an exterior major surface thereof. The UV blocking coating is discontinuous and patterned to form a plurality of design elements, the design elements being positioned across the major surface of the substrate, and the design elements being sized, shaped, and arranged such that at least some design elements are oriented at angles that are neither normal nor substantially normal nor parallel nor substantially parallel to at least some of the other design elements, and such that openings between design elements in the UV blocking coating on average are no greater than a predetermined surface area.

In addition to the features of the previous paragraph, in certain example embodiments, the design elements may not overlap one another. Alternatively, in addition to the features of the previous paragraph, in certain example embodiments, at least some of the design elements may overlap one another, e.g., in a manner and/or to an extent specified by a user.

In addition to the features of either of the two previous paragraphs, in certain example embodiments, the design elements may have a common shape which may be, for example, substantially rectangular, substantially circular, etc.

In addition to the features of any of the three previous paragraphs, in certain example embodiments, the design elements may have a common shape and at least some of the design elements may have different surface areas compared to at least some of the other design elements.

In addition to the features of any of the four previous paragraphs, in certain example embodiments, the design elements may be substantially rectangular and share a common length or a common width, or may be substantially circular and have varying radii.

In addition to the features of any of the five previous paragraphs, in certain example embodiments, the design elements may have different surface areas that have a predefined average surface area and/or vary by no more than a predefined amount.

In addition to the features of any of the six previous paragraphs, in certain example embodiments, all or substantially all of the design elements may have identical or substantially identical dimensions.

In addition to the features of the previous paragraph, in certain example embodiments, design elements proximate to one or more peripheral edges of the substrate may not be dimensioned to be identical or substantially identical to other design elements.

In addition to the features of any of the eight previous paragraphs, in certain example embodiments, each design element may be a composite of multiple design elements.

In addition to the features of the previous paragraph, in certain example embodiments, each design element may be a composite of multiple design elements of the same general shape.

In addition to the features of any of the 10 previous paragraphs, in certain example embodiments, the predetermined surface area may be defined by a length and width.

In addition to the features of any of the 11 previous paragraphs, in certain example embodiments, the predetermined surface area may be approximately 2″ by 2″ or 2″ by 4″.

In addition to the features of any of the 12 previous paragraphs, in certain example embodiments, the predetermined surface area may be defined at least in part based on a specified wingspan and/or height dimension.

In addition to the features of any of the 13 previous paragraphs, in certain example embodiments, design elements may be sized, shaped, and arranged so as to have a density that varies across the major surface of the substrate.

In addition to the features of any of the 14 previous paragraphs, in certain example embodiments, the substrate may be a glass substrate.

In addition to the features of any of the 15 previous paragraphs, in certain example embodiments, wherein the positions, rotations, and/or sizes of the design elements may be determined randomly.

In addition to the features of any of the 16 previous paragraphs, in certain example embodiments, the positions, rotations, and/or sizes of the design elements may be determined randomly within one or more bounded range(s), e.g., with the bounded range(s) potentially being defined in connection with respective minimum and/or maximum values.

In addition to the features of any of the 17 previous paragraphs, in certain example embodiments, the coating may be sputter deposited or printed.

In addition to the features of any of the 18 previous paragraphs, in certain example embodiments, the coating may be formed over a mask, patterned via a laser, and/or the like.

In certain example embodiments, a method of making a laminated product or insulating glass (IG) unit is provided. The method includes having a coated article made in accordance with any of the 19 previous paragraphs; and building the coated article into the laminated product or IG unit.

In certain example embodiments, a method of making a pattern template for use in creating the pattern from any of the 20 previous paragraphs is provided, the method comprising executing computer-programmed instructions to define the pattern and/or pattern template.

In addition to the features of the previous paragraph, in certain example embodiments, user input adjusting the size, shape, positioning, rotation, and/or density of all, some, or one of the design elements for the pattern template may be received; and the pattern template may be modified in accordance with the received user input.

In addition to the features of either of the two previous paragraphs, in certain example embodiments, the coating may be directly formed in the pattern using the pattern template. For instance, the direct formation may include printing the pattern in accordance with the defined pattern template in certain example embodiments. As an alternative, in addition to the features of either of the two previous paragraphs, in certain example embodiments, the coating may be indirectly formed in the pattern using the pattern template. For instance, the coating may be blanket coated on the substrate and the blanket coated coating may be patterned in accordance with the pattern template in certain example embodiments. In certain example embodiments, patterning may be performed using a laser.

In addition to the features of any of the three previous paragraphs, in certain example embodiments, a mask corresponding to the pattern template may be formed.

In certain example embodiments, there is provided a non-transitory computer readable storage medium storing instructions that when executed perform the method of any one of the 24 preceding paragraphs. Similarly, in certain example embodiments, there is provided a computing system comprising at least one processor and a memory, the memory storing instructions that when executed perform the method of any one of the 24 preceding paragraphs.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A coated article, comprising:
a substrate supporting a UV blocking coating on an exterior major surface thereof;
wherein the UV blocking coating is discontinuous and patterned to form a plurality of design elements, the design elements being positioned across the major surface of the substrate, and the design elements being sized, shaped, and arranged such that at least some design elements are oriented at angles that are neither normal nor substantially normal nor parallel nor substantially parallel to at least some of the other design elements, and such that openings between design elements in the UV blocking coating on average are no greater than a predetermined surface area.

2. The coated article of claim 1, wherein the design elements do not overlap one another.

3. The coated article of claim 1, wherein at least some of the design elements overlap one another in a manner and/or to an extent specified by a user.

4. The coated article of claim 1, wherein the design elements have a common shape.

5. The coated article of claim 4, wherein the common shape is substantially rectangular or substantially circular.

6. The coated article of claim 1, wherein the design elements have a common shape and at least some of the design elements have different surface areas compared to at least some of the other design elements.

7. The coated article of claim 6, wherein the design elements are substantially rectangular and share a common length or a common width.

8. The coated article of claim 6, wherein the design elements are substantially circular and have varying radii.

9. The coated article of claim 1, wherein all or substantially all of the design elements have identical or substantially identical dimensions.

10. The coated article of claim 9, wherein design elements proximate to one or more peripheral edges of the substrate are not dimensioned to be identical or substantially identical to other design elements.

11. The coated article of claim 1, wherein each design element is a composite of multiple design elements.

12. The coated article of claim 11, wherein each design element is a composite of multiple design elements of the same general shape.

13. The coated article of claim 1, wherein design elements are sized, shaped, and arranged so as to have a density that varies across the major surface of the substrate.

14. The coated article of claim 1, wherein the positions, rotations, and/or sizes of the design elements are determined randomly.

15. The coated article of claim 1, wherein the positions, rotations, and/or sizes of the design elements are determined randomly within one or more bounded range(s), wherein the bounded range(s) is/are defined in connection with respective minimum and/or maximum values.

16. An insulating glass (IG) unit, comprising:
the coated article of claim 1;
a second substrate;
a spacer system helping to maintain the coated article and the second substrate in substantially parallel spaced apart relation to one another, such that a gap is formed between the coated article and the second substrate and such that the UV blocking coating is oriented away from the second substrate.

17. A method of making a coated article, the method comprising:
having a substrate; and
forming a UV blocking coating on an exterior major surface thereof;
wherein the UV blocking coating is discontinuous and patterned to form a plurality of design elements, the design elements being positioned across the major surface of the substrate, and the design elements being sized, shaped, and arranged such that at least some design elements are oriented at angles that are neither normal nor substantially normal nor parallel nor substantially parallel to at least some of the other design elements, and such that openings between design elements in the UV blocking coating on average are no greater than a predetermined surface area.

18. The method of claim 17, wherein the design elements do not overlap one another.

19. The method of claim 17, wherein at least some of the design elements overlap one another in a manner and/or to an extent specified by a user.

20. The method of claim 17, wherein the design elements have a common shape.

21. The method of claim 17, wherein the design elements have a common shape and at least some of the design elements have different surface areas compared to at least some of the other design elements.

22. The method of claim 21, wherein the design elements have different surface areas that have a predefined average surface area and/or vary by no more than a predefined amount.

23. The method of claim 17, wherein all or substantially all of the design elements have identical or substantially identical dimensions.

24. The method of claim 23, wherein design elements proximate to one or more peripheral edges of the substrate are not dimensioned to be identical or substantially identical to other design elements.

25. The method of claim 17, wherein each design element is a composite of multiple design elements.

26. The method of claim 17, wherein design elements are sized, shaped, and arranged so as to have a density that varies across the major surface of the substrate.

27. The method of claim 17, wherein the positions, rotations, and/or sizes of the design elements are determined randomly.

28. The method of claim 17, wherein the positions, rotations, and/or sizes of the design elements are determined randomly within one or more bounded range(s), wherein the bounded range(s) is/are defined in connection with respective minimum and/or maximum values.

29. The method of claim 17, wherein the coating is sputter deposited or printed.

30. The method of claim 17, wherein the coating is sputter deposited or printed over a mask.

31. A method of making a pattern template for use in creating the pattern of claim 17, the method comprising executing computer-programmed instructions to define the pattern and/or pattern template.

32. The method of claim 31, further comprising:
receiving user input adjusting the size, shape, positioning, rotation, and/or density of all, some, or one of the design elements for the pattern template; and
modifying the pattern template in accordance with the received user input.

33. The method of claim 31, further comprising directly forming the coating in the pattern using the pattern template.

34. The method of claim 31, further comprising blanket coating the coating on the substrate and patterning the blanket coated coating in accordance with the pattern template.

35. A non-transitory computer readable storage medium storing instructions that when executed perform the method of claim 31.

36. A computing system comprising at least one processor and a memory, the memory storing instructions that when executed perform the method of claim 31.
